(19) United States
(12) Patent Application Publication
(10) Pub. No.: US 2007/0031599 A1
(43) Pub. Date: Feb. 8, 2007

(54) Use of dissolved hafnium alkoxides or zirconium alkoxides as precursors for hafnium oxide and hafnium oxynitride layers or zirconium oxide and zirconium oxynitride layers

(76) Inventors: Alexander Gschwandtner, Muenchen (DE); Martin Knapp, Laufen (DE)

Correspondence Address: JENKINS, WILSON, TAYLOR & HUNT, P. A., 3100 TOWER BLVD, SUITE 1200, DURHAM, NC, 27707, US

(21) Appl. No.: 11/493,083

(22) Filed: Jul. 26, 2006

Related U.S. Application Data
(63) Continuation of application No. PCT/EP05/01034, filed on Feb. 2, 2005.

(30) Foreign Application Priority Data
Feb. 3, 2004 (DE) 102004005385.5

(51) Int. Cl. C23C 16/00; C23C 16/40

(52) U.S. Cl. 427/248.1; 106/287.19

(57) ABSTRACT

The present invention relates to the use of a highly concentrated solution of one or more hafnium alkoxides as precursors for hafnium oxide and hafnium oxynitride layers. The present invention relates in particular to the use of a 30 to 90% strength by weight solution of one or more hafnium alkoxides for producing hafnium oxide and hafnium oxynitride layers for CVD or ALD methods. In addition, the invention relates to a process for the production of a hafnium oxide and hafnium oxynitride layer on an article to be coated, and a hafnium alkoxide solution which contains 30 to 90% by weight of one or more hafnium alkoxides. In a further embodiment of the invention, hafnium is replaced by zirconium in said compounds.

### RELATED APPLICATIONS

This application is a continuation of PCT International Patent Application No. PCT/EP2005/001034, filed Feb. 2, 2005, which claims priority to German Patent Application No. 102004005385.5, filed Feb. 3, 2004, the disclosures of each of which are incorporated herein by reference in their entitety.

The present invention relates to the use of a solution of one or more hafnium or zirconium alkoxides as precursors for hafnium oxide and hafnium oxynitride layers or zirconium oxide and zirconium oxynitride layers. The present invention relates in particular to the use of a 30 to 90% strength by weight solution of one or more hafnium alkoxides or zirconium alkoxides for producing hafnium oxide and hafnium oxynitride layers or zirconium oxide and zirconium oxynitride layers by CVD or ALD methods. In addition, the invention relates to a process for the production of a hafnium oxide and hafnium oxynitride layer or zirconium oxide and zirconium oxynitride layers on an article to be coated, and a hafnium alkoxide solution or zirconium alkoxide solution which contains 30 to 90% by weight of one or more hafnium alkoxides or zirconium alkoxides.

Hafnium oxide and hafnium oxynitride layers are the first choice for future generations of semiconductor components as a dielectric both for MOS transistors in logic modules and for capacitors in memory modules, in particular the good temperature stability of the layers in combination with a high dielectric constant distinguishing the material compared with other metal oxides.

A further important application of hafnium oxide or oxynitride as a dielectric is that for integrated capacitors, so-called MIM (metal-insulator-metal) capacitors in the wiring plane of logic modules, the metal planes being used as electrodes. In this application, the high chemical stability of hafnium oxide to the nonnoble electrode material, such as titanium nitride and tantalum nitride, in addition to the high dielectric constant compared with silicon nitride or aluminum oxide is advantageous.

Proposed solutions to date for depositing hafnium oxide or oxynitride layers are based on the use of hafnium chloride, liquid long-chain undiluted hafnium alkoxides and hafnium-aminoalkyl precursors.

Hafnium chloride is a solid having a very low vapor pressure, chlorine also being incorporated in the electrical during the deposition of the layers and the electrical properties thus being adversely affected. Moreover, the edge covering is insufficient.

Although liquid long-chain hafnium alkoxides have a sufficiently high vapor pressure for CVD and ALD methods, the thermal stability of the substances is not sufficient for achieving good edge covering on difficult topographies.

Hafniumaminoalkyl precursors have good properties with respect to incorporated carbon in the layer and also very good edge covering, but the material costs are so high that their use for capacitors in memory modules and MIM capacitors appears questionable.

A list of the most well known precursors and the manner in which they are used according to the prior art in the production of HfO₂ layers are listed below.

The general problem with the use of the precursors is that transition metals of groups IVB and VB have a strong tendency to reach six-fold coordination with ligands. Dimers and oligomers which have low volatility and make it difficult or even impossible to carry out the CVD or ALD methods therefore form.
1. HF halides: HfX₄; X=Cl, I
   Reaction: HfX₄+2 H₂O=>HfO₂+4 HX

Hf halides are highly reactive ALCVD and CVD precursors. Problems exist with regard to low volatility and—as mentioned above—undesired incorporation of halides in the Hf oxide layer.
2. HF nitrate: Hf(NO₃)₄

The main problem with Hf nitrates is their explosiveness.
3. HF alkylamides: Hf(NR′R″)₄; R′ and R″=CH₃, C₂H₅

Hf alkylamides are reacted in a reaction with H₂O, O₃, O radicals, NH₃ or NOx radicals. They are highly reactive ALCVD precursors. The main problems of their use are the very complicated preparation process and hence their extremely high price.
4. HF complexes: Hf(mpp)₄, Hf(acac)₄

Marked features are a high C content and low growth rates. Examples are Hf alkoxides: Hf(OR)₄ R=CH₃, C₂H₅, (iso-) C₃H₇, (tert-) C₄H₉. A reaction is effected with H₂O, O₃, O radicals and O₂. The Hf complexes can be used as MOCVD precursors and partially as ALCVD precursors. Problems arise through their properties as solids having low volatility (except for Hf(tert-C₄H₉)₄; however, there is the problem of poor film quality here; Hf(tert-C₄H₉)₄ can therefore be used only as an MOCVD precursor).

The following specific examples may be mentioned as known hafnium precursors:

HF Alkoxides:

Hafnium methoxide Hf(OMe)₄ 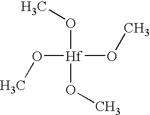
Molecular Weight=302.63
Molecular Formula=C4H12HfO4
Molecular Composition=C 15.88% H 4.00% Hf 58.98% O 21.15%
Properties: white solid at room temperature;
melting point 50° C.;
remarks: highest Hf content of all alkoxides.

Hafnium ethoxide: Hf(OEt)₄ 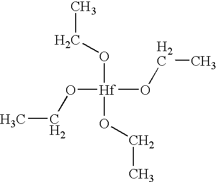
Molecular Weight=358.74
Molecular Formula=C8H20HfO4
Molecular Composition=C 26.79% H 5.62% Hf 49.76% O 17.84%
CAS Reg. No. 13428-80-3
Properties: white solid at room temperature

Hafnium n-propoxide: Hf(n-Pr)₄ 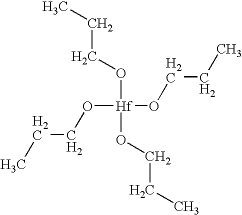
Molecular Weight=414.84
Molecular Formula=C12H28HfO4
Molecular Composition=C 34.74% H 6.80% Hf 43.03% O 15.43%
CAS Reg. No. 25491-66-1
Properties: white solid at room temperature; delta H sub 0=83.7+−8.4 kJ/mol (Lappert, M. F. et al.; J. Chem. Soc. Chem. Commun., 830 (1975))

Problem: low thermal stability

Hafnium tert-butoxide: HF(t-Bu)₄
CAS Reg. No. 2172-02-3
Properties: liquid at room temperature; vapor pressure 2 mmHg at 75° C.; remarks: thermally unstable (cf. decomposition route); high volatility owing to steric hindrance by bulky tert-butoxide groups

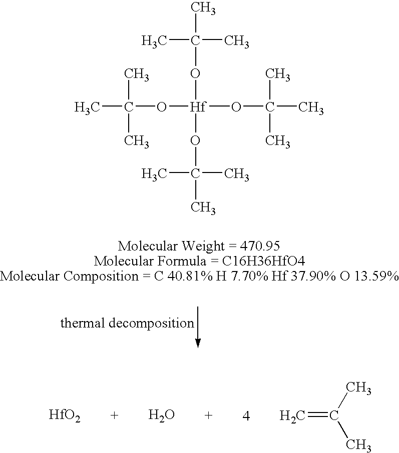

Hafnium 1-methoxy-2-methyl-2-propanolate: Hf(mmp)₄ 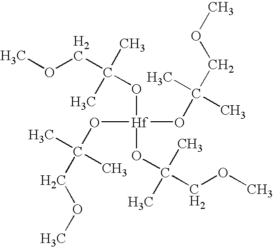
Molecular Weight=591.06
Molecular Formula=C20H44HfO8
Molecular Composition=C 40.64% H 7.50% Hf 30.20% O 21.66%
CAS Reg. No. 309915-48-8
Properties: liquid at room temperature (melting point 15° C.); vapor pressure 0.1 mmHg at 100° C.; 7.6 mmHg at 135° C.
Remarks: low growth rate owing to bulky ligands.
   Hf Alkylamides

Tetrakis(dimethylamino)hafnium: TDMAH Hf(NMe₂)₄ 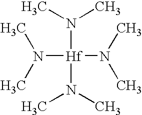
Molecular Weight=354.80
Molecular Formula=C8H24HfN4
Molecular Composition=C 27.08% H 6.82% Hf 50.31% N 15.79%
CAS Reg. No. 19782-68-4,19962-11-9
Properties: solid at room temperature; melting point 26-29° C.; vapor pressure 0.1 mmHg at 48° C.; thermal decomposition >90° C.

Tetrakis(ethylmethylamino)hafnium: TEMAH Hf(NEtMe)₄ 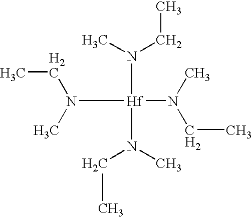
Molecular Weight=410.91
Molecular Formula=C12H32HfN4
Molecular Composition=C 35.08% H 7.85% Hf 43.44% N 13.63%
CAS Reg. No. 352535-01-4
Properties: liquid at room temperature; vapor pressure 0.1 mmHg at 79° C.

Tetrakis(diethylamino)hafnium TDEAH: Hf(NEt₂)₄ 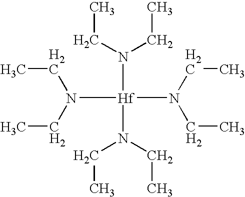
Molecular Weight=467.01
Molecular Formula=C16H40HfN4
Molecular Composition=C 41.15% H 8.63% Hf 38.22% N 12.00%
CAS Reg. No. 19824-55-6, 19962-12-0
Properties: vapor pressure 0.01 mmHg at 130° C.; 0.1 mmHg at 96° C.
Remarks: low vapor pressure

Hafnium hydroxylamine: Hf(ONR₂)₄ R=Me, Et
Remarks: Poor film morphology, narrow ALD temperature range at 300° C.
   Process for the Production of HfO₂ Layers

In principle, various processes for the deposition of hafnium oxide or hafnium oxynitride layers are known in the prior art. These can be divided into ALCVD and CVD processes.

The CVD process (chemical vapor deposition=CVD) is the chemical conversion of a reaction gas consisting of one or more volatile compounds into a solid substance and volatile byproducts. For deposition of the layer, the reaction gas is passed over the substrate to be coated.

Usually, processes for chemical gas-phase deposition are categorized according to the operating gas pressure, the determining activation method and deposition temperature and reactor wall temperature. A distinction is made here between atmospheric pressure CVD (APCVD=atmospheric pressure CVD), low pressure CVD (LPCVD=low pressure CVD) and plasma CVD (PCVD or PECVD=plasma enhanced CVD).

When organometallic compounds are used, the MOCVD (metal organic CVD or organometallic CVD) variant is referred to. Finally, so-called RPE-ALCVD or RPE-MOCVD can also be used (remote plasma enhanced CVD process). These processes are described below:

RPE-MOCVD (remote plasma enhanced metal organic CVD): RPE-ALCVD (remote plasma enhanced atomic layer CVD): The thermal decomposition of the organometallic compound is promoted by the introduction of excited and ionized gases into the reactor. The excitation of the gases is effected in an external plasma chamber (remote plasma) and the gases are then introduced into the reactor, the gases being present as neutral species (so-called radicals) or still partly as ions.

Radicals (e.g. O, N, H) can be passed in simultaneously with the layer deposition (RPE-MOCVD, or preferably sequentially in RPE-ALCVD). The precursor feed is interrupted at certain time intervals and the layer already deposited is treated with radicals. As a result, the following improvements of the layer are achieved:
achievement of exact stoichiometries (e.g. incorporation of O into oxide layers)
removal of organic residues—reduction of the C content
incorporation of N into oxide layers (oxynitrides through N radicals)
improved electrical properties (leakage current, dielectric strength, capacitance)

For a further explanation of deposition processes which can be used in the context of the present invention, reference may be made to several papers in the technical literature, for example Mikroelektronik-Technologie, edited by Prof. Dr sc. techn. K. Schade, Verlag Technik GmbH, Berlin-Munich, 1991, and Nanoelectronics and Information Technology, Reiner Waser (editor), Wiley-VCH, Weinheim, 2003.

General problems with the use of these technologies occur in the provision of sufficient amounts of precursors, in particular for batch reactors; otherwise, a diffusion-controlled CVD with poor uniformity or extremely long cycle times (e.g. in the case of ALCVD) is effected.

It is therefore the object of the present invention to overcome the problems occurring in the case of the hafnium oxide precursors of the prior art, for example formation of residues and the high cost factor and the frequently occurring poor edge covering on difficult topography. It is also the object of the present invention to provide precursors for the hafnium oxide or hafnium oxynitride deposition which can be used in a sufficient amount and also concentration for batch reactors. It was furthermore the object of the present invention to provide precursors for the abovementioned purpose which can be used for a very wide range of deposition methods with sufficiently high deposition rates.

These objects are achieved by the subject of the independent claims. Preferred embodiments are described in the dependent claims.

The abovementioned problems are solved by using a solution of one or more hafnium alkoxides or zirconium alkoxides as a precursor for hafnium oxide and hafnium oxynitride layers or zirconium oxide and zirconium oxynitride layers. It has surprisingly been found that, by using a solution instead of the undiluted starting material, the problems occurring in the prior art and relating to poor volatility arising through complex formation (see above) can be overcome.

The present invention relates to the preparation of economical, highly concentrated solutions of short-chain Hf alkoxides or zirconium alkoxides, which are usually present as a solid, and the use of these solutions as economical precursors for the production of hafnium or zirconium oxide or oxynitride layers with the aid of, preferably, MOCVD and/or ALCVD processes for the mass production of integrated circuits.

The precursor costs of these dissolved Hf alkoxides are only about 10% compared with the Hf alkylamides currently preferred in the prior art.

In a first aspect, the present invention relates to the use of a solution of one or more hafnium alkoxides as a precursor for hafnium oxide and hafnium oxynitride layers.

According to the invention, it is also possible to use a further element of group IVb, namely zirconium, instead of hafnium. Zirconium has properties similar to those of hafnium, although it is somewhat less advantageous in some respects (higher leakage currents).

The present invention therefore also relates to the use of a solution of one or more zirconium alkoxides as a precursor for zirconium oxide and zirconium oxynitride layers. All embodiments carried out above and below with regard to hafnium therefore also apply correspondingly to zirconium.

According to a preferred embodiment, the solution according to the invention is highly concentrated. In particular, the use of a 30-90% strength by weight solution of one or more hafnium alkoxides as a precursor for hafnium oxide and hafnium oxynitride layers is suitable. A preferred range is 50-80% by weight of hafnium alkoxide in solution. For example, a ratio of hafnium alkoxide: solvent of 2-3:1 is suitable.

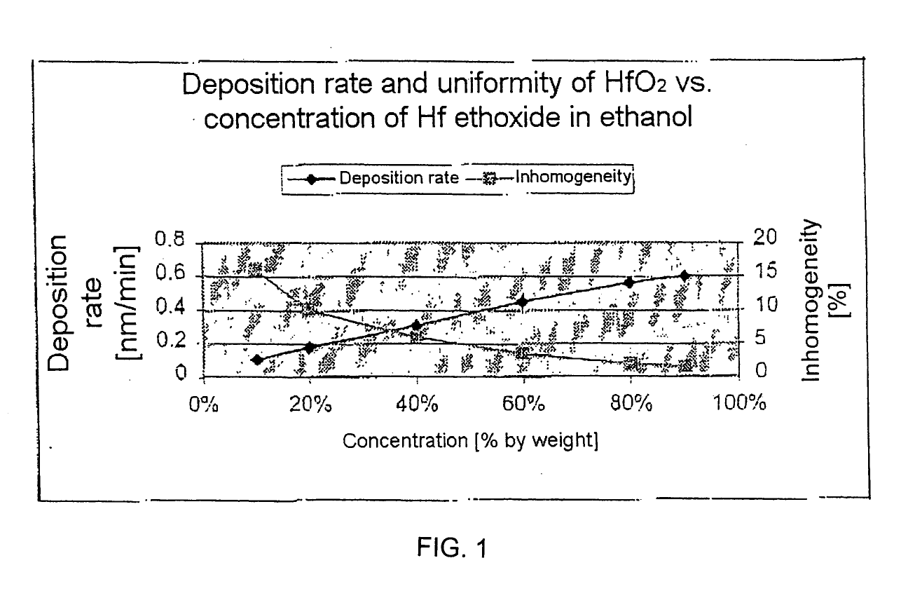

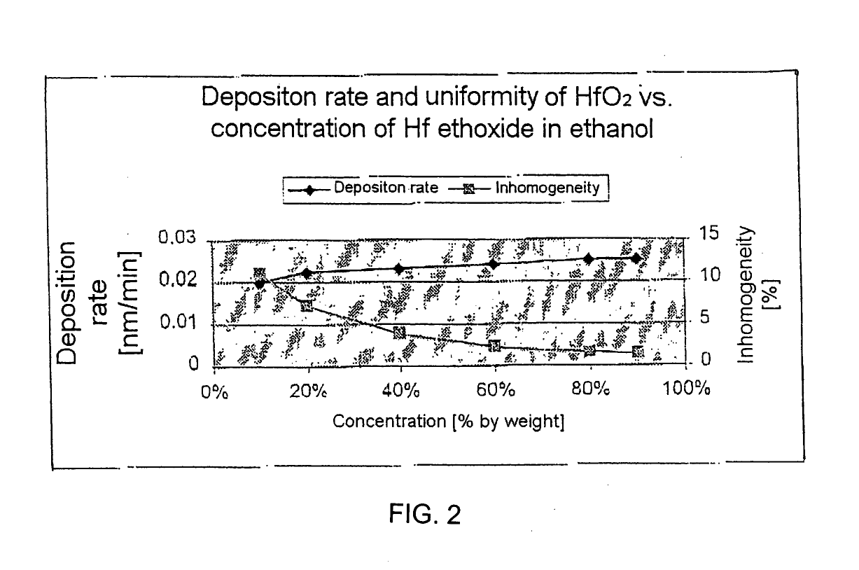

These ranges have arisen for the following reasons: at a concentration above 90%, the solutions are difficult to process owing to the excessively high viscosity. Below a concentration of 30%, on the other hand, there is a clear tendency to form inhomogeneities (cf. FIGS. 1 and 2). For most producers, inhomogeneities of <5% are tolerable in practice, so that a concentration above 50% is to be particularly preferred.

For example, FIG. 1 shows that the inhomogeneities are below the critical limit of 5% from a concentration of about >50%. FIG. 2 shows that this critical limit is not reached even from a range of a concentration of about 30%.

In all cases, the deposition rate of the solutions according to the invention increases with increasing concentration.

According to a further embodiment, the solutions defined above are used for the production of hafnium oxide and hafnium oxynitride layers by CVD or ALD processes. The deposition of the hafnium oxide or hafnium oxynitride layer on capacitors or transistors or as an optical layer on laser mirrors is particularly suitable here. Owing to its high refractive index, the hafnium oxide layer can be used as an optical layer of laser mirrors (the refractive index of hafnium oxide is about 2.1).

According to the invention, hafnium methoxide, hafnium n-propoxide, hafnium isopropoxide and/or hafnium ethoxide are preferably used as hafnium alkoxides. Among these, hafnium methoxide and hafnium ethoxide in a range of 30-90% by weight are particularly preferred. Relatively high growth rates in the ALCVD process are achieved in particular by small ligands (methoxide, ethoxide).

According to the invention, suitable zirconium alkoxides are consequently zirconium methoxide, zirconium ethoxide, etc.

The solvent for the preparation of the solution according to the invention preferably has a polar group.

Solvents having a polar group or free electron pairs which, by coordination to the hafnium (or zirconium), increase its coordination number to 6 (e.g. Hf(OR)₄·2 ROH; R=Me, Et, etc.) and thus break coordinate bonds between a plurality of hafnium alkoxide molecules (oligomerization) are particularly preferred. The complexing of the hafnium by solvent molecules also explains the very good solubility.

For example, the preferred solution of Hf(OEt)₄ in EtOH with 80% by weight is Hf(OEt)₄·2 EtOH.

Preferred classes of substances are: alcohols, amines, ethers or esters.

According to the invention, it has proven particularly advantageous to use an alcoholic solvent as the solvent. An alcoholic solvent preferably comprises one or more straight-chain or branched C₂-C₈-alcohols, e.g. ethanol, propanol, butanol, isopropyl alcohol, etc. As discussed above, the alcohol may be straight-chain or branched and may be formed from a primary, secondary or tertiary alcohol.

According to the invention, the alcoholic solvent can furthermore also be used in combination with a cosolvent. Suitable cosolvents are all customary substances, but in particular high-boiling solvents. The advantageous high-boiling (b.p. 100-250° C.) cosolvent optionally serves for further dilution of the solution. This may be necessary, inter alia, in order to prevent condensation of the precursor in the injection apparatus.

In principle, all classes of solvents (see above) are suitable. Relatively long-chain alcohols are suitable only if no exchange with the alcoholates bonded to the Hf occurs.

The solvent which is most advantageous in the present invention comprises or consists of EtOH. In particular, a solution containing hafnium ethoxide has given the best results here.

According to a second aspect, the present invention provides a process for the production of a hafnium or zirconium oxide layer on an article to be coated, which comprises the following steps:
a) provision of a solution as defined above and of an article to be coated;
b) introduction of the solution into a reactor and vaporization of the solution in the reactor, or
c) vaporization of the solution and introduction of the vapor into a reactor; and
d) deposition of the vapor on the article for the formation of a hafnium or zirconium oxide layer.

Regarding the introduction of the solution, reference is made to the publication: “Developments in CVD Delivery Systems: A Chemist's Perspective on the Chemical and Physical Interactions Between Precursors” by Paul O'Brien et al., Chem. Vap. Deposition 2002, 8, No. 6, in its entirety.

According to an embodiment, step c) is effected by liquid injection into the heated antechamber of the reactor, by pulsed liquid injection or aerosol vaporization.

Deposition processes which may be used are all deposition processes which are known and can be used in the prior art. The MOCVD, RPE-MOCVD, ALCVD or RPE-ALCVD process is preferably used.

According to a further embodiment, the hafnium oxide layer can be further reacted by nitriding by means of a nitrogen-containing gas for the production of a hafnium oxynitride layer. N₂, NH₃, N₂O or mixtures thereof are preferably used as nitrogen-containing gases.

The inventors have found that NH₃ as a nitrogen-containing gas or coprecursor gives the best results. It is therefore most preferred.

A further improvement in the electrical properties of the layers can be achieved by sequential ozone or remote plasma treatment in the MOCVD and ALD mode by so-called RPE-MOCVD and RPE-ALD processes. By burning out the carbon by means of ozone or oxygen radicals and by incorporation of nitrogen by means of nitrogen radicals, the thermal and chemical properties of the layer are improved.

The hafnium oxide layer produced by the process according to the invention is therefore optionally aftertreated with ozone or oxygen radicals.

Furthermore, the hafnium oxides or oxynitrides deposited according to the invention preferably by MOCVD, RPE-MOCVD, ALCVD or RPE-ALCVD from dissolved alkoxides can be used for the preparation of hafnium silicon oxide or hafnium silicon oxynitride by sequential deposition with the silicon alkoxide TEOS.

In addition, mixed oxides or oxynitrides, such as, for example, hafnium-aluminum, hafnium-tantalum, hafnium-titanium, hafnium-lanthanum, etc., or even ternary mixed hafnium oxides, such as, for example, hafnium aluminum tantalum, can be produced by sequential deposition with other precursors.

As already discussed above, for example, an MOS transistor, a capacitor or a laser mirror can be coated by the process according to the invention.

According to a third aspect, the present invention provides a hafnium alkoxide solution which contains 30-90% by weight of one or more hafnium alkoxides, the hafnium alkoxide being selected from hafnium methoxide, hafnium n-propoxide, hafnium isopropoxide and/or hafnium ethoxide.

According to a preferred embodiment, the hafnium alkoxide solution is a 30-90% strength by weight solution of hafnium ethoxide in ethanol.

The present invention is now described with reference to embodiments and figures.

The figures show the following:

FIG. 1: deposition of hafnium oxide in the CVD mode in an A400 reactor from ASM. A sufficient homogeneity over the wafers is achieved only at high concentration of Hf ethoxide in ethanol. The deposition rate shows a linear dependence on the concentration.

FIG. 2: deposition of hafnium oxide in the ALD mode in an A400 reactor from ASM. A sufficient homogeneity over the wafers is achieved in the ALD mode too only at high concentration of Hf ethoxide in ethanol. The deposition rate shows less dependence on the Hf ethoxide concentration in ethanol.

### EMBODIMENTS

1.1. MOCVD or RPE-MOCVD of Hafnium Oxide or Oxynitride

1.1.1 Hafnium Oxide

| | |
|---|---|
| Precursor: | Hf(OC₂H₅)₄ dissolved in C₂H₅OH |
| Process temperature: | 250-450° C. |
| Pressure: | 5-200 Pa |
| Deposition rate: | 0.1-5 nm/min |

Deposition of HfO₂ in the CVD mode in an A400 reactor from ASM with 125 wafers in the boat. Wafer diameter 200 mm.

| | |
|---|---|
| Process temperature: | 390° C. |
| Pressure: | 35 Pa |
| Deposition rate: | cf. FIG. 1 |
| Precursor: | Hf ethoxide dissolved in ethanol |
| Gas flow: | 1 slm nitrogen as carrier gas |
| Precursor flow: | 0.75 g/min |

FIG. 1 shows in this context the deposition of hafnium oxide in the CVD mode in an A400 reactor from ASM. A sufficient homogeneity over the wafers is achieved only at high concentration of Hf ethoxide in ethanol. The deposition rate shows a linear dependence on the concentration.

1.1.2 Hafnium Oxynitride

| | |
|---|---|
| Precursor: | Hf(OC₂H₅)₄ dissolved in C₂H₅OH |
| Coprecursor: | ammonia |
| Process temperature: | 250-450° C. |
| Pressure: | 5-200 Pa |
| Deposition rate: | 0.1-5 nm/min |

1.2. Sequential Aftertreatment by Oxidation or Nitriding of the Layer

Oxidation by Ozone or Oxygen Radicals from Remote Plasma

| | |
|---|---|
| Process temperature: | 250-450° C. |
| Ozone concentration: | 10% by volume in oxygen |

Oxygen radicals from remote plasma:

| | |
|---|---|
| Gases: | oxygen, nitrous oxide |
| Pressure: | 5-200 Pa |
| Microwave power: | 2-6 kW |

By sequential oxidation with ozone or oxygen radicals at intervals of 3 nm at a temperature of 390° C., it was possible to reduce the leakage current at a field strength of 2 MV/cm from 5 10E-7 to 1 10E-8/cm².

Nitriding by Nitrogen Radicals from Remote Plasma:

| | |
|---|---|
| Gases: | nitrogen, ammonia |
| Microwave power: | 2-6 kW |

By sequential nitriding with nitrogen radicals at intervals of 3 nm at a temperature of 390° C., it was possible to reduce the leakage current at a field strength of 2 MV/cm from 5 10E-7 to 5 10E-9/cm².

2. ALD or RPE-ALD of Hafnium Oxide or Oxynitride

2.1 Hafnium Oxide

| | |
|---|---|
| First precursor: | Hf(OC₂H₅)₄ dissolved in C₂H₅OH |
| Process temperature: | 200-400° C. |
| Pressure: | 5-200 Pa |
| Deposition rate: | 0.05-0.5 nm/min |
| Second precursor: | H₂O, ozone, oxygen radicals |

2.2 Hafnium Oxynitride

| | |
|---|---|
| First precursor: | Hf(OC₂H₅)₄ dissolved in C₂H₅OH |
| Coprecursor: | ammonia |
| Process temperature: | 200-400° C. |
| Pressure: | 5-200 Pa |
| Deposition rate: | 0.05-0.5 nm/min |
| Second precursor: | H₂O, ozone, ammonia, oxygen radicals, nitrogen |
| | radicals, mixtures of nitrogen, ammonia and |
| | oxygen in the excited state |
| Microwave power: | 2-6 kW |

Deposition of HfO₂ in the ALD mode in an A400 reactor from ASM with 125 wafers in the boat. Wafer diameter 200 mm.

| | |
|---|---|
| Process temperature: | 240° C. |
| Pressure: | 50 Pa |
| Deposition rate: | cf. FIG. 2 |
| Precursor: | Hf ethoxide dissolved in ethanol |
| Gas flow: | 1.5 slm nitrogen as carrier gas |
| Precursor flow: | 0.75 g/min |

FIG. 2 shows the relevant deposition of hafnium oxide in the ALD mode in an A400 reactor from ASM. A sufficient homogeneity over the wafers is achieved in the ALD mode too only at high concentration of Hf ethoxide in ethanol. The deposition rate shows only a slight dependence on the Hf ethoxide concentration in ethanol.

On deposition in the RPE-ALD mode it is possible to reduce the leakage current at a field strength of 2 MV/cm from 8 10E-8 to 3 10E-9/cm² by using nitrogen radicals as the second precursor at a deposition temperature of 240° C.

The deposition of the layers was effected both on single wafer lines and on batch lines having a loading up to 160 product wafers.

The hafnium oxide or oxynitride layer deposited by MOCVD or RPE-MOCVD and ALCVD or RPE-ALCVD are distinguished by very good edge covering on difficult topographies with aspect ratios of 50 (depth/height of a structure) in combination with very good electrical properties, low contamination level of carbon or chlorine and low precursor costs compared with all other hafnium precursors.

1. The use of a solution of one or more hafnium alkoxides or zirconium alkoxides as a precursor for hafnium oxide and hafnium oxynitride layers or for zirconium oxide and zirconium oxynitride layers, a 30-90% strength by weight solution of one or more hafnium alkoxides being used as precursor for hafnium oxide and hafnium oxynitride layers or a 30-90% strength by weight solution of one or more zirconium alkoxides being used as a precursor for zirconium oxide and zirconium oxynitride layers.

2. The use as claimed in claim 1, a 50-80% strength by weight solution being used.

3. The use as claimed in one or more of the preceding claims, the hafnium oxide and hafnium oxynitride layers being produced by CVD or ALD processes.

4. The use as claimed in one or more of the preceding claims, the hafnium oxide or hafnium oxynitride layer being produced on capacitors or transistors or as an optical layer on laser mirrors.

5. The use as claimed in one or more of the preceding claims, the hafnium alkoxides used being hafnium methoxide, hafnium n-propoxide, hafnium isopropoxide and/or hafnium ethoxide.

6. The use as claimed in one or more of the preceding claims, the solution comprising 30-90% of hafnium methoxide.

7. The use as claimed in one or more of claims 1-5, the solution comprising 30-90% by weight of hafnium ethoxide.

8. The use as claimed in one or more of the preceding claims, the solution comprising, in addition to hafnium alkoxide, a solvent having a polar group.

9. The use as claimed in claim 8, the solvent being an alcoholic solvent.

10. The use as claimed in claim 9, the solvent comprising one or more straight-chain or branched C₂-C₈-alcohols.

11. The use as claimed in one or more of the preceding claims 9-10, the solvent comprising EtOH and/or the solution comprising hafnium ethoxide.

12. The use as claimed in one or more of the preceding claims, hafnium being replaced by zirconium in said compounds.

13. A process for the production of a hafnium oxide layer or zirconium oxide layer on an article to be coated, which comprises the following steps:
a) provision of a solution as defined in one or more of claims 1-12 and of an article to be coated;
b) introduction of the solution into a reactor and vaporization of the solution in the reactor, or
c) vaporization of the solution and introduction of the vapor into a reactor;
d) deposition of the vapor on the article for the formation of a hafnium oxide layer or zirconium oxide layer.

14. The process as claimed in claim 13, step c) being effected by liquid injection into the heated antechamber of the reactor, by pulsed liquid injection or aerosol vaporization.

15. The process as claimed in claim 13 or 14, the deposition process used being the MOCVD, RPE-MOCVD, ALCVD or RPE-ALCVD process.

16. The process as claimed in one or more-of claims 13-15, nitriding by means of a nitrogen-containing gas for the production of a hafnium oxynitride layer additionally being effected.

17. The process as claimed in claim 16, the gas used being N₂, NH₃, N₂O or a mixture thereof.

18. The process as claimed in one or more of the preceding claims, in which NH₃ is used as the nitrogen-containing gas or coprecursor.

19. The process as claimed in one or more of the preceding claims, hafnium being replaced by zirconium in said compounds.

20. The process as claimed in one or more of claims 14-19, the article being an MOS transistor, a capacitor or a laser mirror.

21. A hafnium alkoxide solution which contains 30-90% by weight of one or more hafnium alkoxides, the hafnium alkoxides being selected from hafnium methoxide, hafnium n-propoxide, hafnium isopropoxide and/or hafnium ethoxide, or a zirconium alkoxide solution which contains 30-90% by weight of one or more zirconium alkoxides, the zirconium alkoxides being selected from zirconium methoxide, zirconium n-propoxide, zirconium isopropoxide and/or zirconium ethoxide.

22. The hafnium alkoxide solution as claimed in claim 21, which is a 30-90% strength by weight solution of hafnium ethoxide in ethanol, or the zirconium alkoxide solution as claimed in claim 21, which is a 30-90% strength by weight solution of zirconium ethoxide.
